(19) United States
(12) Patent Application Publication
(10) Pub. No.: US 2026/0106573 A1
(43) Pub. Date: Apr. 16, 2026

(54) TRANSIMPEDANCE AMPLIFIER FOR HIGH-CURRENT PHOTONIC APPLICATIONS OR OTHER APPLICATIONS

(71) Applicant: Raytheon Company, Tewksbury, MA (US)

(72) Inventors: Matthew A. Morton, Lynnfield, MA (US); Zhaoyang C. Wang, Carlisle, MA (US)

(21) Appl. No.: 18/914,946

(22) Filed: Oct. 14, 2024

(51) Int. Cl. H03F 1/02; H03F 3/45

(52) U.S. Cl. CPC H03F 1/0205; H03F 3/45475; H03F 2200/372; H03F 2200/451

(57) ABSTRACT

An apparatus includes a transimpedance amplifier having at least one input and an output. The apparatus also includes at least one controllable first current source configured to control at least one input current to a selected input current provided to the at least one input of the transimpedance amplifier. The at least one controllable first current source may connect to the at least one input of the transimpedance amplifier and may be configured to drain a DC current from the at least one input current applied to the at least one input of the transimpedance amplifier. The apparatus may include a second current source, a first resistor connected between a first input of the at least one input of the transimpedance amplifier and the second current source, and a second resistor connected between a second input of the at least one input of the transimpedance amplifier and the second current source.

### TECHNICAL FIELD

This disclosure relates generally to transimpedance amplifiers. More specifically, this disclosure relates to a transimpedance amplifier for high-current photonic applications or other applications.

### BACKGROUND

A transimpedance amplifier (TIA) is a device that converts an electrical current into an electrical voltage. Among other uses, a TIA can be used to provide an interface between a photonic integrated circuit and an analog-to-digital converter (ADC). Often times, a TIA needs to handle large currents produced by a photonic integrated circuit. Conventional TIA applications operate with low-power photonic integrated circuits that feed low-amplitude current into a TIA. The lower input current leads to solutions that have low noise and low power consumption. However, these applications do not work well for high-current applications.

### SUMMARY

This disclosure relates to a transimpedance amplifier for high-current photonic applications or other applications.

In some examples, an apparatus includes a transimpedance amplifier having at least one input and an output. The apparatus also includes at least one controllable first current source configured to control at least one input current to a selected input current provided to the at least one input of the transimpedance amplifier.

Any single one or any combination of the following features may be used with the examples above. The at least one controllable first current source may connect to the at least one input of the transimpedance amplifier and may be configured to drain a DC current from the at least one input current applied to the at least one input of the transimpedance amplifier. A controllable current value may set the at least one controllable first current source to set an input bias voltage level to the transimpedance amplifier. The apparatus may include a transimpedance amplifier current source within the transimpedance amplifier and configured to control performance of the transimpedance amplifier. The transimpedance amplifier current source may be set to optimize performance of the transimpedance amplifier. The apparatus may include a second current source, a first resistor connected between a first input of the at least one input of the transimpedance amplifier and the second current source, and a second resistor connected between a second input of the at least one input of the transimpedance amplifier and the second current source. The second current source, the first resistor, and the second resistor may be configured to provide a low impedance to handle large RF swings at the at least one input of the transimpedance amplifier. The second current source, the first resistor, and the second resistor may be configured to minimize diode distortion from a connected photonic integrated circuit. The apparatus may include a photonic integrated circuit configured to generate the at least one input current and connected to the at least one input of the transimpedance amplifier. The apparatus may include an analog-to-digital converter connected to the output of the transimpedance amplifier.

In other examples, an apparatus includes a transimpedance amplifier having at least one input and an output. The apparatus also includes a first current source connected to the at least one input of the transimpedance amplifier and configured to drain a DC current from at least one input current applied to the at least one input of the transimpedance amplifier. The apparatus further includes a photonic integrated circuit configured to generate the at least one input current and connected to the at least one input of the transimpedance amplifier. In addition, the apparatus includes an analog-to-digital converter connected to the output of the transimpedance amplifier.

Any single one or any combination of the following features may be used with the examples above. A controllable current value may set the first current source to set an input bias voltage level to the transimpedance amplifier. The apparatus may include a transimpedance amplifier current source within the transimpedance amplifier and configured to control performance of the transimpedance amplifier. The transimpedance amplifier current source may be set to optimize performance of the transimpedance amplifier. The apparatus may include a second current source, a first resistor connected between a first input of the at least one input of the transimpedance amplifier and the second current source, and a second resistor connected between a second input of the at least one input of the transimpedance amplifier and the second current source. The second current source, the first resistor, and the second resistor may be configured to provide a low impedance to handle large RF swings at the at least one input of the transimpedance amplifier. The second current source, the first resistor, and the second resistor may be configured to minimize diode distortion from the photonic integrated circuit.

In still other examples, a method includes connecting at least one controllable first current source to at least one input of a transimpedance amplifier. The method also includes receiving at least one input current at the at least one input of the transimpedance amplifier. The method further includes controlling the at least one input current to a selected input current provided to the at least one input of the transimpedance amplifier using the at least one controllable first current source.

Any single one or any combination of the following features may be used with the examples above. Controlling the at least one input current may include draining a DC current from the at least one input current applied to the at least one input of the transimpedance amplifier using the at least one controllable first current source connected to the at least one input of the transimpedance amplifier. Controlling the at least one input current may include setting a controllable current value for the at least one controllable first current source to set an input bias voltage level to the transimpedance amplifier. The method may include controlling performance of the transimpedance amplifier using a controllable transimpedance amplifier current source within the transimpedance amplifier. The method may include providing a low impedance to handle large RF swings at the at least one input of the transimpedance amplifier using a second current source and at least one resistor. Providing the low impedance may include minimizing diode distortion from a connected photonic integrated circuit.

Other technical features may be readily apparent to one skilled in the art from the following figures, descriptions, and claims.

### BRIEF DESCRIPTION OF THE DRAWINGS

For a more complete understanding of this disclosure and its advantages, reference is now made to the following description taken in conjunction with the accompanying drawings, in which like reference numerals represent like parts:

FIG. 1 illustrates an example transimpedance amplifier (TIA) interconnected between a photonic integrated circuit and an analog-to-digital converter in accordance with this disclosure;

FIG. 2 illustrates an example TIA having one or more associated current sources for draining input DC current in accordance with this disclosure;

FIG. 3 illustrates example circuitry in the TIA of FIG. 2 in accordance with this disclosure; and

FIG. 4 illustrates example operation of the circuitry of FIG. 3 in accordance with this disclosure.

### DETAILED DESCRIPTION

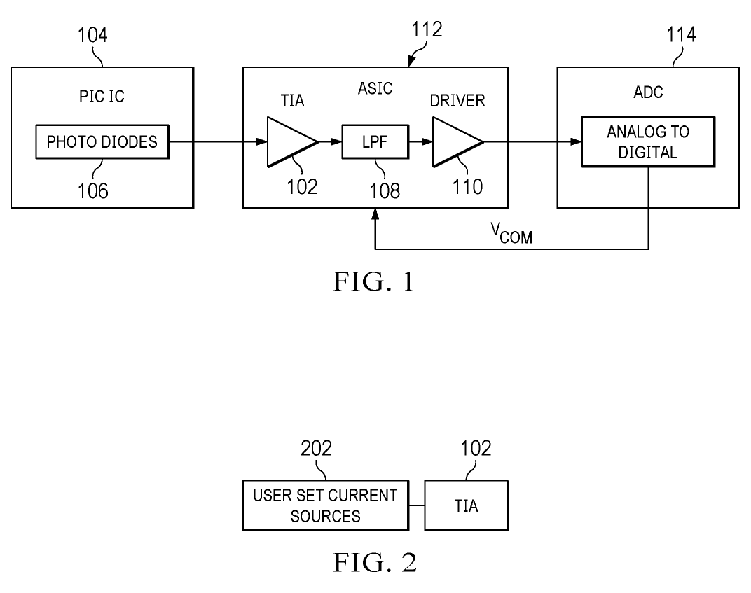

FIGS. 1 through 4, described below, and the various embodiments used to describe the principles of the present disclosure are by way of illustration only and should not be construed in any way to limit the scope of this disclosure. Those skilled in the art will understand that the principles of the present disclosure may be implemented in any type of suitably arranged device or system.

FIG. 1 illustrates an example transimpedance amplifier (TIA) 102 interconnected between a photonic integrated circuit (PIC) 104 and an analog-to-digital converter (ADC) 114 in accordance with this disclosure. More specifically, the TIA 102 in this example has an input connected to an output of the PIC 104. The PIC 104 includes one or more photodiodes 106 therein to provide electrical current output to the TIA 102. The TIA 102 has its output connected to a low pass filter 108, and an output of the low pass filter 108 is connected to a driver circuit 110. In some embodiments, the TIA 102, low pass filter 108, and driver circuit 110 may be implemented within an application-specific integrated circuit (ASIC) 112. An output from the ASIC 112 is provided to the ADC 114. The TIA 102 here therefore provides an interface between the PIC 104 and the ADC 114.

In some embodiments, the TIA 102 needs to be able to handle large DC currents that are produced by the photodiodes 106 within the PIC 104. Previous approaches have made use of blocking capacitors in order to block large DC currents. However, the implementation described here handles the large currents from the PIC 104 without the use of DC blocking capacitors. Additionally, the TIA 102 can have the ability to level-shift its output to a desired DC output voltage level in order to interact with different commercial off-the-shelf or other ADCs 114.

FIG. 2 illustrates an example TIA 102 having one or more associated current sources 202 for draining input DC current in accordance with this disclosure. As shown in FIG. 2, the controllable current source(s) 202 may enable a number of input-side goals to be achieved with respect to the TIA 102. As particular examples, these input-side goals may include providing 0.1-50 mA DC sink current, providing 0.1-50 mA AC input current, providing low AC input impedance, and/or providing a fixed 3V input bias. Note, however, that each of these values or ranges is for illustration only and can easily vary.

Among other things, the controllable current source(s) 202 may allow the TIA 102 to handle large PIC currents from the photodiodes 106 for both DC an RF currents while maintaining suitable noise levels, power levels, and linearity of performance of the TIA 102. These results are achieved as more fully described below by controlling the operation of the current source(s) 202 connected to the input(s) of the TIA 102. In some cases, the controllable current source(s) 202 may represent at least one user-controllable current source.

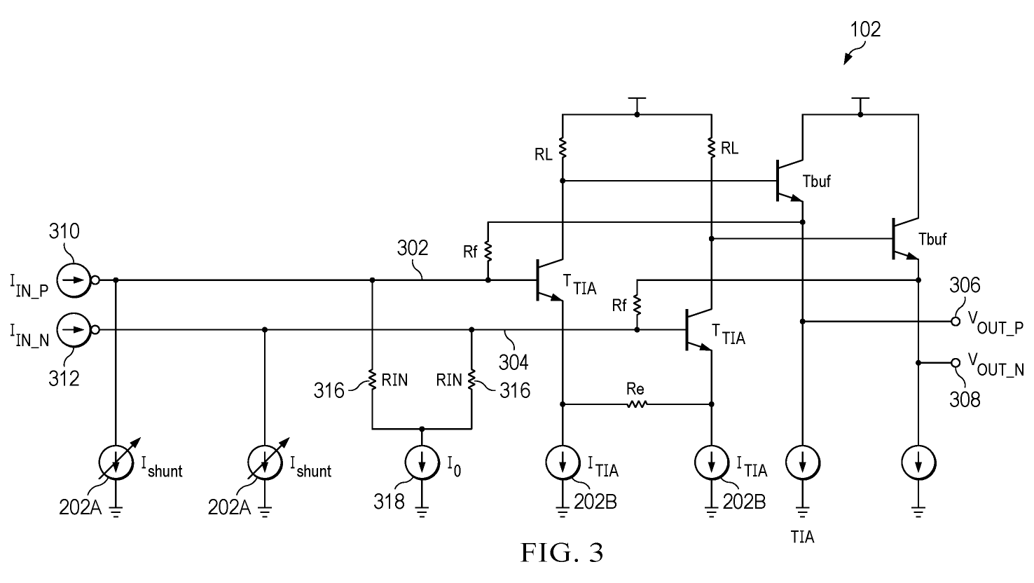

FIG. 3 illustrates example circuitry in the TIA 102 of FIG. 2 in accordance with this disclosure. More specifically, FIG. 3 represents a schematic diagram of the controllable current source(s) 202 and the circuitry in the TIA 102. The TIA 102 includes a configuration having inputs at nodes 302 and 304 and outputs at nodes 306 and 308. The controllable current source(s) 202 can be connected to the node(s) 302 and/or 304. Input current from each of the photodiodes 106 of the PIC 104 may be provided individually at each of the nodes 302, 304 as an input current 310, 312. Responsive to the input currents 310, 312, the TIA 102 can generate an output voltage through the nodes 306 and 308.

In this example, a current source Iₛₕᵤₙₜ202A is connected to each of the input nodes 302 and 304 of the TIA 102 to drain DC current from the input currents 310, 312, respectively. In some cases, a user may manually select a value of the current source Iₛₕᵤₙₜ202A to select a desired level of DC current to be drained from the input currents 310, 312. Also connected to the input nodes 302 and 304 of the TIA 102 are input resistors Rᵢₙ316 and a current source I₀318. Low values of the input resistors Rᵢₙ316 and a small current source I₀318 can provide a low input impedance at the input of the TIA 102, such as to handle a large current signal swing from the PIC 104 or other source and to maintain low PIC diode distortion. The input voltage bias of the TIA 102 can be set to a desired level, such as by a user, through selection of the current source Iₛₕᵤₙₜ202A while setting the current source I_{TIA}202B to support optimum performance of the TIA 102.

By establishing the current sources Iₛₕᵤₙₜ202A and I_{TIA}202B in this fashion, the TIA 102 may handle large currents from the photodiodes 106 of the PIC 104 and maintain optimum performance of the TIA 102 with no extra DC power consumption. The controlled current source Iₛₕᵤₙₜ202A can remove excessive DC current by draining it from the input current. An input circuit including the resistors 316 and the current source 318 can set up a low impedance input to handle large RF swings from the input currents of the PIC 104. High DC and RF currents can be handled separately to reduce current density requirements for the circuit. Among other things, the above described circuit configuration can provide required DC voltage bias for the TIA 102 and the photodiodes 106 while allowing the TIA current to be tuned for optimum TIA performance.

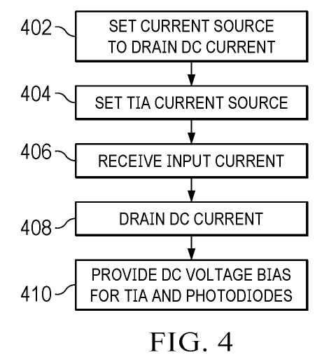

FIG. 4 illustrates example operation of the circuitry of FIG. 3 in accordance with this disclosure. As shown in FIG. 4, the current source Iₛₕᵤₙₜ202A can be set to a desired level at step 402 (such as by a user) to drain DC current from the input currents 310 and 312. The current source I_{TIA}202B can be set at step 404 (such as by the user) to a level to support optimum TIA performance. The input currents can be received at the TIA 102 at step 406. The current source Iₛₕᵤₙₜ202A can drain the DC current from the received input currents at step 408 as established by the current source Iₛₕᵤₙₜ202A. The DC bias voltage for the TIA 102 and the photodiodes 106 can be provided at step 410.

It may be advantageous to set forth definitions of certain words and phrases used throughout this patent document. The term “couple” and its derivatives refer to any direct or indirect communication between two or more components, whether or not those components are in physical contact with one another. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present disclosure should not be read as implying that any particular element, step, or function is an essential or critical element that must be included in the claim scope. The scope of patented subject matter is defined only by the allowed claims. Moreover, none of the claims invokes 35 U.S.C. § 112(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. An apparatus comprising:
a transimpedance amplifier having at least one input and an output; and
at least one controllable first current source configured to control at least one input current to a selected input current provided to the at least one input of the transimpedance amplifier.

2. The apparatus of claim 1, wherein the at least one controllable first current source connects to the at least one input of the transimpedance amplifier and is configured to drain a DC current from the at least one input current applied to the at least one input of the transimpedance amplifier.

3. The apparatus of claim 2, wherein a controllable current value sets the at least one controllable first current source to set an input bias voltage level to the transimpedance amplifier.

4. The apparatus of claim 1, further comprising:
a transimpedance amplifier current source within the transimpedance amplifier and configured to control performance of the transimpedance amplifier.

5. The apparatus of claim 4, wherein the transimpedance amplifier current source is set to optimize performance of the transimpedance amplifier.

6. The apparatus of claim 1, further comprising:
a second current source;
a first resistor connected between a first input of the at least one input of the transimpedance amplifier and the second current source; and
a second resistor connected between a second input of the at least one input of the transimpedance amplifier and the second current source;
wherein the second current source, the first resistor, and the second resistor are configured to provide a low impedance to handle large RF swings at the at least one input of the transimpedance amplifier.

7. The apparatus of claim 6, wherein the second current source, the first resistor, and the second resistor are configured to minimize diode distortion from a connected photonic integrated circuit.

8. The apparatus of claim 1 further comprising:
a photonic integrated circuit configured to generate the at least one input current and connected to the at least one input of the transimpedance amplifier; and
an analog-to-digital converter connected to the output of the transimpedance amplifier.

9. An apparatus comprising:
a transimpedance amplifier having at least one input and an output;
a first current source connected to the at least one input of the transimpedance amplifier and configured to drain a DC current from at least one input current applied to the at least one input of the transimpedance amplifier;
a photonic integrated circuit configured to generate the at least one input current and connected to the at least one input of the transimpedance amplifier; and
an analog-to-digital converter connected to the output of the transimpedance amplifier.

10. The apparatus of claim 9, wherein a controllable current value sets the first current source to set an input bias voltage level to the transimpedance amplifier.

11. The apparatus of claim 9, further comprising:
a transimpedance amplifier current source within the transimpedance amplifier and configured to control performance of the transimpedance amplifier.

12. The apparatus of claim 11, wherein the transimpedance amplifier current source is set to optimize performance of the transimpedance amplifier.

13. The apparatus of claim 9, further comprising:
a second current source;
a first resistor connected between a first input of the at least one input of the transimpedance amplifier and the second current source; and
a second resistor connected between a second input of the at least one input of the transimpedance amplifier and the second current source; and
wherein the second current source, the first resistor, and the second resistor are configured to provide a low impedance to handle large RF swings at the at least one input of the transimpedance amplifier.

14. The apparatus of claim 13, wherein the second current source, the first resistor, and the second resistor are configured to minimize diode distortion from a connected photonic integrated circuit.

15. A method comprising:
connecting at least one controllable first current source to at least one input of a transimpedance amplifier;
receiving at least one input current at the at least one input of the transimpedance amplifier; and
controlling the at least one input current to a selected input current provided to the at least one input of the transimpedance amplifier using the at least one controllable first current source.

16. The method of claim 15, wherein controlling the at least one input current comprises draining a DC current from the at least one input current applied to the at least one input of the transimpedance amplifier using the at least one controllable first current source connected to the at least one input of the transimpedance amplifier.

17. The method of claim 16, wherein controlling the at least one input current comprises setting a controllable current value for the at least one controllable first current source to set an input bias voltage level to the transimpedance amplifier.

18. The method of claim 15 further comprising:
controlling performance of the transimpedance amplifier using a controllable transimpedance amplifier current source within the transimpedance amplifier.

19. The method of claim 15, further comprising:
providing a low impedance to handle large RF swings at the at least one input of the transimpedance amplifier using a second current source and at least one resistor.

20. The method of claim 19, wherein providing the low impedance comprises minimizing diode distortion from a connected photonic integrated circuit.
